(19) United States
(12) Patent Application Publication
(10) Pub. No.: US 2025/0365867 A1
(43) Pub. Date: Nov. 27, 2025

(54) Adapter for Enabling the Interchange of Integrated Circuits with Dissimilar Surface Mount Device Footprints

(71) Applicant: Scott Thomas McGimpsey, Fort collins, CO (US)

(72) Inventor: Scott Thomas McGimpsey, Fort collins, CO (US)

(21) Appl. No.: 18/674,917

(22) Filed: May 27, 2024

(51) Int. Cl. H05K 1/14; H01L 23/00; H05K 1/11

(52) U.S. Cl. CPC H05K 1/141; H05K 1/11; H05K 1/144; H01L 24/16; H01L 24/48; H01L 2224/16225; H01L 2224/48227; H01L 2924/15311; H05K 2201/049; H05K 2201/06; H05K 2201/09218; H05K 2201/10689

(57) ABSTRACT

The invention is an adapter enabling the interchange of the use of Integrated Circuit components on a Printed Circuit Board with a dissimilar Surface Mount Device footprint with minimal impact to total component height and no obstruction of typical optical inspection methods. The invention indirectly resolves common constraints of electronic circuit designs, such as IC obsolescence, market availability, and design improvements without discarding existing materials.

### BACKGROUND OF THE INVENTION

The invention pertains to the field of electronic circuit design and manufacturing, specifically to the limitation existing for a surface mount device (SMD) integrated circuit (IC) of some associated package type requiring an interface of metal pads (footprint) of compatible design to permit installation (population) on a printed circuit board (PCB) with footprint of a design intended for an SMD package dissimilar to that of the IC.

The dissimilarity between the footprint necessary to accommodate the leads for the package of an associated IC, and the footprint available on a PCB is characterized by differences in the size, spacing, and geometry of the metal pads intended to conduct electrical current, thermal energy, or both, between the IC and the PCB.

The ability to overcome this limitation can be desirable or necessary to remedy situations where use of an IC with a package compatible to the available PCB footprint causes a condition which, but for the stated limitation, would be resolved or mitigated through use of an IC which is only available in an incompatible package. Such a condition may include one or more of the following: limited market availability, higher cost, lower power efficiency, absence of functionality or features, undesirable height of package, undesirable performance of some key characteristic.

There exist some devices which address the presented limitation, but introduce new complexities and limitations which will be unacceptable for many circuit designs and manufacturing processes. One class of devices which remove the presented limitation makes use of a substructure of formed leads (metal legs) which are compatible with a footprint available on the PCB, attaching to a carrier for the desired IC. Formed legs are generally considered to introduce significant cost to a device due to the associated complexity of forming and attaching the legs. The formed legs of this device introduce additional height to PCB which may interfere with enclosures or other components. Additionally, the metal legs do not provide a thermally conductive path between the IC and PCB, which can lead to early failure of a circuit. Another class of device relies upon surface mount installation of a carrier which completely covers the footprint available on the PCB, wherein the mating pads are blind soldered to the PCB. This solution does not suffer from the cost or complexity of formed-leads. However, this device introduces manufacturing limitations by preventing visible access to the soldered interface which precludes use of common post-assembly optical inspection techniques of PCB assemblies. These inspection techniques are important to ensuring the quality of produced assemblies, and reducing production costs.

Therefore, there exists a need for a device that can enable interface between an SMD IC package and an incompatible PCB footprint, but with reduced inherent complexity, and few impacts to common design constraints such as height or thermal conductivity, while permitting post-assembly inspection and future rework. The present invention seeks to address this need.

### SUMMARY OF THE INVENTION

The invention is an adapter which enables installation of an integrated circuit of some associated surface mount package to a PCB footprint designed for a different, incompatible package. This adapter includes a guest interface for the IC package, a host interface for the PCB footprint, and interconnecting traces to ensure proper electrical routing. The adapter maintains minimal overall height and incorporates metal-plated half-holes to allow for optical inspection and rework post-assembly.

### BRIEF DESCRIPTION OF DRAWINGS

FIG. 1 depicts an isometric view of the top and sides of an expression of the adapter, illustrating the adapter substrate (1), the metal-plated half-holes (2), the connecting traces (3), and pads of the IC footprint providing the guest interface (4).

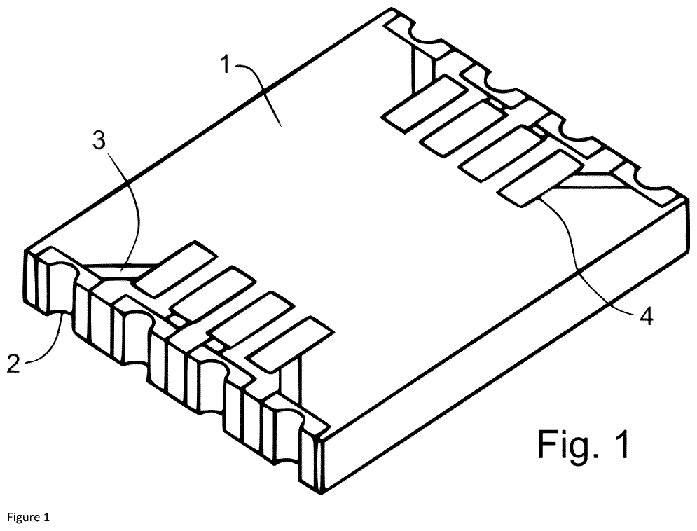

FIG. 2 depicts an isometric view showing the bottom surface of an expression of the adapter, illustrating the host interface (5).

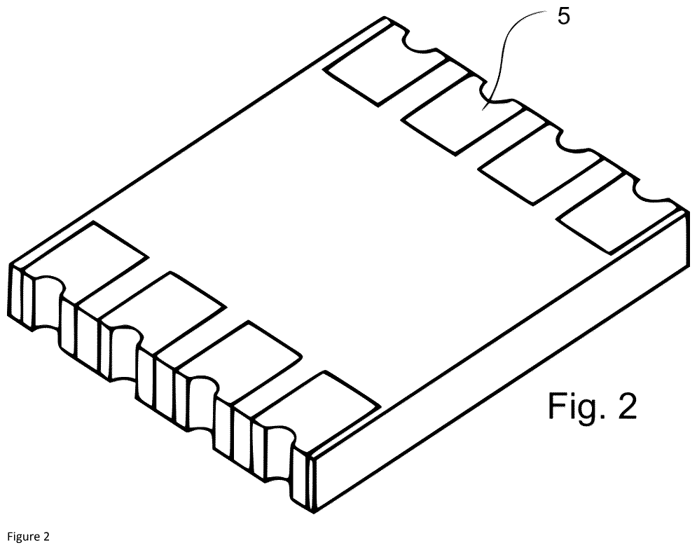

FIG. 3 depicts a profile view illustrating an expression of the adapter wherein the adapter is shown (8) providing electrical and mechanical interface between host PCB (10) and guest IC (6). The interface is completed by a host-to-adapter solder connection (9) and an adapter-to-guest solder connection (7).

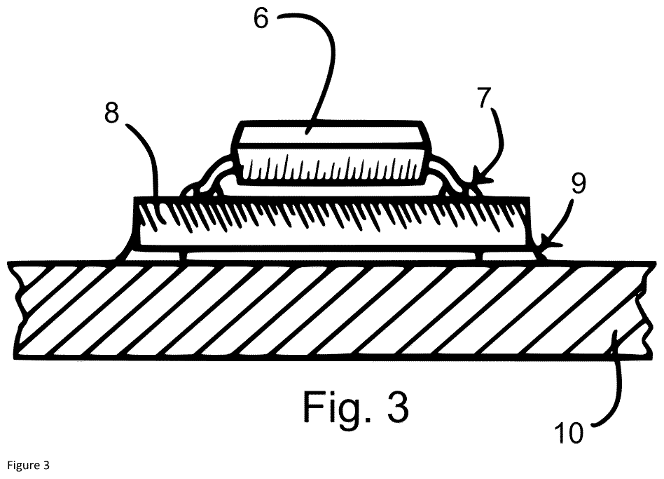

FIG. 4 depicts a profile view of the adapter from FIG. 3, rotated ninety degrees around the axis perpendicular from the top surface of the illustrated host PCB.

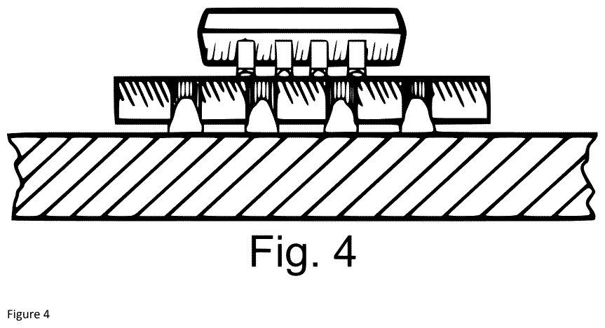

FIG. 5 depicts an isometric view of an expression of the adapter in which the guest interface is a footprint tailored to an IC with pins on four sides, and a host interface with a similar style footprint. The guest-interface side thermal interface pad of the thermal bridge (1) is also illustrated, along with vias (also known as plated through-holes) for the purpose of providing a thermally conductive path from the guest IC, through the adapter, to the host PCB.

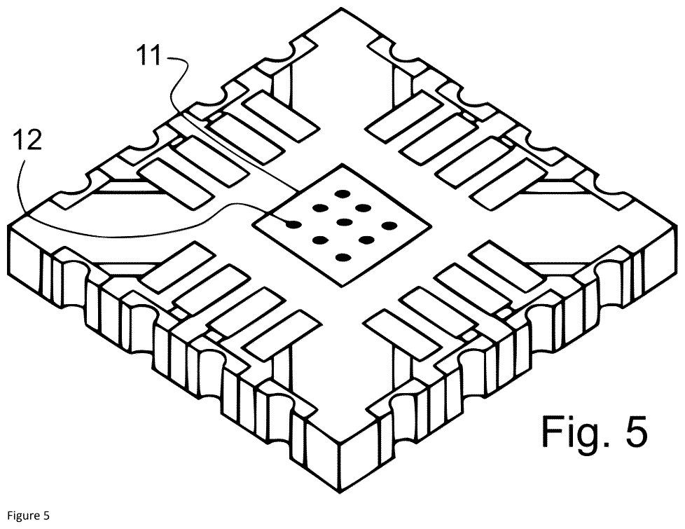

FIG. 6 depicts an isometric view of an expression of the adapter which is shown soldered to the pads a PCB footprint (13). Also illustrated is the solder mechanically and electrically connecting the adapter to the PCB (14) and an example of how the design permits direct inspection of the solder joint for quality issues, such as absent solder (15).

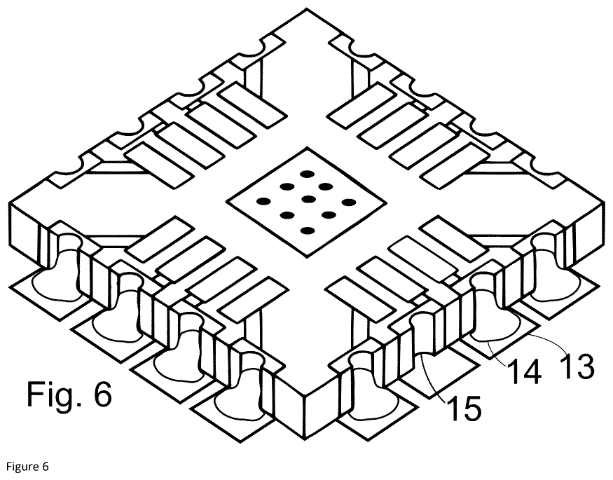

### DETAILED DESCRIPTION OF THE INVENTION

The invention is an adapter which provides a mechanical and electrical interface between an IC and PCB, where the footprint required for installation of the package of the guest IC is dissimilar from the footprint available on the host PCB.

The invention optionally supports inclusion of a thermal bridge to conduct thermal energy between the IC and the PCB.

A footprint is an arrangement of the metal pads necessary to mechanically and electrically connect an IC and a PCB through the use of solder.

The connection of the thermal pad of an IC to the thermal pad of the host footprint is optionally possible through the use of a thermal bridge, which makes use of metal pads on the top and bottom of the adapter, and connected through plated metal holes.

When used in reference to an IC, a package is the combination of a body enclosing an IC, and metal leads which may be soldered to a footprint to provide mechanical connection to a PCB and electrical connection to a circuit. Some IC packages also provide for a larger central pad which is used to conduct thermal energy away from the IC to increase device longevity.

The term “guest footprint” describes the footprint necessary on an expression of an adapter to connect a specific IC package to the adapter.

The term “host footprint” describes the footprint available on a PCB.

The term “envelope” is used to describe the smallest two-dimensional convex polygon containing all points of another two-dimensional object.

The adapter comprises a host interface, a guest interface, interconnecting traces, and may include a path for thermal conduction between the guest footprint and the host footprint.

An embodiment of the adapter exists for the interface of any IC package with any available footprint on a PCB within set constraints.

The first constraint for embodiments of the device is that an envelope of the host interface does not touch, intersect or exceed an envelope of the host footprint.

The second constraint for embodiments of the device is that the envelope of the guest footprint does not touch, intersect, or exceed the envelope of the host interface.

The third constraint for embodiments of the device is that at least one of the pads comprising the guest footprint has an electrical connection through the adapter to one of the pads of the host interface.

The fourth constraint for embodiments of the adapter are that the adapter is for the interface of two surface mount IC packages.

For each pad of the host footprint, the host interface requires a mating pad on the underside of the adapter, a metal-plated half-hole on the side of the adapter, and an interconnecting pad on the topside of the adapter. The mating pad controls the flow of solder in a way which reinforces mechanical strength of the adapter to the PCB. The metal-plated half-hole provides access to the surface of the solder after installation to permit optical inspection for quality control, to permit use as an electrical test-point, and to permit manual rework of the PCB.

Where an embodiment of the device provides an interface for thermal energy between the guest interface and the host interface, the thermal pad on the guest interface is closely matched to the geometry of the IC thermal pad, and the thermal pad on the host interface is closely matched with geometry of the host footprint.

Two embodiments illustrate the versatility of the adapter. The first embodiment connects a host PCB with a SOIC-8 3.9×4.9 mm 1.27 mm pitch footprint to a guest IC with a DFN-8 4×4 mm 0.8 mm pitch footprint. Each pin of the host interface is routed via connecting traces to the corresponding pin of the guest interface. A second embodiment connects a host PCB with a 64-LQFP 14×14 mm 0.8 mm pitch footprint to a guest IC with a 64-LQFP 10×10 mm 0.5 mm pitch footprint. Additional embodiments are realized to support interfacing of footprints of other surface mount packages including dual-in-line (example: small-outline integrated circuit), quad-in-line (example: quad flat package), grid-array (example: ball grid array).

This detailed description is intended to cover all such modifications and variations. It must be understood that the scope of the invention, as defined by the appended claims, may extend beyond the specific embodiments described herein.

1. Adapter comprising a substrate; a guest interface; a host interface, and; a plurality of connecting traces.

2. Adapter comprising a substrate; a host interface; a guest interface; a plurality of connecting traces, and; a thermal bridge.

3. An adapter according to claim 1 or 2, in which the substrate is a square or rectangular rigid sheet of electrically insulative material or composite.

4. An adapter according to claim 1 or 2, in which the guest interface comprises an arrangement of exposed metal pads located on one side of the adapter.

5. An adapter according to claim 1 or 2, in which the host interface comprises an arrangement of exposed metal plated half-holes along either two sides or four sides of the edge of the substrate; an arrangement of exposed metal pads along the perimeter of the side of the substrate opposite the guest interface, each joining on one side to the exposed metal plated half-holes, and; an arrangement of metal pads on the side of the substrate also containing the guest interface, each joining on one side to the exposed metal plated half-holes.

6. An adapter according to claim 1 or 2, in which the plurality of connecting metal traces attaches one or more pads of the guest interface to one or more pads of the host interface.

7. An adapter according to claim 2, in which a thermal bridge comprises one or more exposed metal pads on the side of the substrate also containing the guest interface; one or more exposed metal pads on the side of the substrate opposite the guest interface, and; an arrangement of metal plated holes which thermally and electrically connect the pads of each side.

8. An adapter according to claim 1 or 2, wherein the guest interface is specifically designed to accommodate one surface mount integrated circuit.

9. An adapter according to claim 1 or 2, wherein the host interface is specifically designed to fit the footprint intended for a surface mount integrated circuit.
